(19) United States
(12) Patent Application Publication
(10) Pub. No.: US 2009/0039458 A1
(43) Pub. Date: Feb. 12, 2009

(54) INTEGRATED DEVICE

(75) Inventors: Philip Stopford, Dresden (DE); Henry Heidemeyer, Dresden (DE); Hans-Peter Moll, Dresden (DE); Olaf Storbeck, Dresden (DE); Regina Hayn, Radeburg (DE); Wieland Pethe, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/837,127

(22) Filed: Aug. 10, 2007

(51) Int. Cl. H01L 29/00; H01L 21/311; H01L 21/762

(52) U.S. Cl. 257/510; 438/437; 438/762; 257/E29.001; 257/E21.546; 257/E21.24

(57) ABSTRACT

A method of fabricating an integrated device on a substrate with an exposed surface region is disclosed. One embodiment provides introducing a first component into the exposed surface region of the substrate. A material is provided on the exposed surface region. The material on the exposed surface region is cured and the first component release from the exposed surface region of the substrate.

### BACKGROUND

Demands imposed on large scale integrated devices, such as memory devices, micro-processors, signal-processors, and the like, are constantly increasing. In the case of such large scale integrated devices, those demands mainly translate into increasing integration and decreasing minimum feature size. As the integration rises, the distance between neighbouring functional entities, as a consequence, shrinks. Since such functional entities, which may include, for example, transistors, resistors, capacitors, isolators, dielectrics, diodes, light-emitting-diodes, semiconductor lasers, light sensors, and/or conductors, may need electrical isolation from each other, the provision of reliable and thin isolators becomes more and more challenging.

As part of efforts to decrease the minimum feature size, so called isolation trenches are introduced into a substrate between neighbouring functional entities. In such a way, a part of the substrate may be removed and/or may be converted into an isolator, such as silicon oxide or silica. Such isolation trenches may be transferred into the substrate by a combination of lithographic, etching, deposition, and structuring techniques, as they are known from the technology of manufacturing highly integrated devices. Thereby, a reliable and complete filling of such isolation trenches may be important to attain desired dielectric, capacitive, and/or isolating characteristics.

Since in some cases the material of the substrate, such as silicon, may be converted into an isolator by using an oxidation, such techniques may be rather common. Furthermore, the isolation trenches may be filled with an isolating filling material, such as a spin-on-glass (SOG) or a spin-on-dielectric (SOD), in order to provide the isolating material. Such materials may require an anneal, a cure and/or a thermal treatment in order to fill the trench, being converted into an oxide, for densification, and/or for other purposes. Such treatment, however, may also lead to an oxidation of further substrate material, which may broaden the effective trench width. Such broadening may be undesirable, since it may counteract a reliable minimization of the feature size and a reliable increase of the integration.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A illustrates a schematic view of a section of an integrated device, according to a first embodiment.

FIG. 1B illustrates a schematic view of a section of an integrated device, according to a second embodiment.

FIG. 1C illustrates a schematic view of a section of an integrated device, according to a third embodiment.

FIGS. 2A through 2D illustrate schematic views of a section of an integrated device in various stages during manufacturing, according to a fourth embodiment.

FIGS. 3A through 3C illustrate schematic views of a section of an integrated device in various stages during manufacturing, according to a fifth embodiment.

FIGS. 4A through 4C illustrate schematic views of a section of an integrated device in various stages during manufacturing, according to a sixth embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

Various embodiments provide for a method of fabricating an integrated device, a method of fabricating an integrated device on a silicon substrate, a method of filling a trench of a silicon substrate, and an integrated device.

One embodiment provides a method of fabricating an integrated device on a substrate. The substrate includes an exposed surface region. The method includes introducing a first component into the exposed surface region of the substrate. A material is provided on the exposed surface region. The material on the exposed surface region is cured, and the first component is released from the exposed surface region of the substrate.

One embodiment provides a method of fabricating an integrated device on a silicon substrate, the silicon substrate having an exposed surface region and the method having a nitridation of the exposed surface region of the silicon substrate; a providing of a precursor material on the exposed surface region; and a curing of the precursor material on the surface region, wherein the precursor material is converted into a first isolating material and the nitrogen is released from the surface region of the substrate.

One embodiment provides a method of filling a trench of a silicon substrate, the method having a nitridation of a surface region of the silicon substrate, the surface region being exposed on a side wall and a bottom wall of the trench; a providing of a precursor material on the exposed surface region, the first material including any from the group of silicon, oxygen, nitrogen, siloxane, a spin-on-dielectric, and a spin-on-glass; and a curing of the precursor material, wherein the precursor material is converted into silicon oxide and the nitrogen is released from the exposed surface region of the silicon substrate.

One embodiment provides an integrated device, the integrated device including a semiconductor substrate, the semiconductor substrate including a trench, the trench being filled with a filling material, and a region of the semiconductor substrate adjacent to a side wall and to bottom wall of the trench being converted into the filling material.

These above-recited features of the present invention will become clear from the following description, taking in conjunction with the accompanying drawings. It is to be noted, however, that the accompanying drawings illustrate only typical embodiments of the present invention and are, therefore, not to be considered limiting of the scope of the invention. The present invention may admit equally effected embodiments.

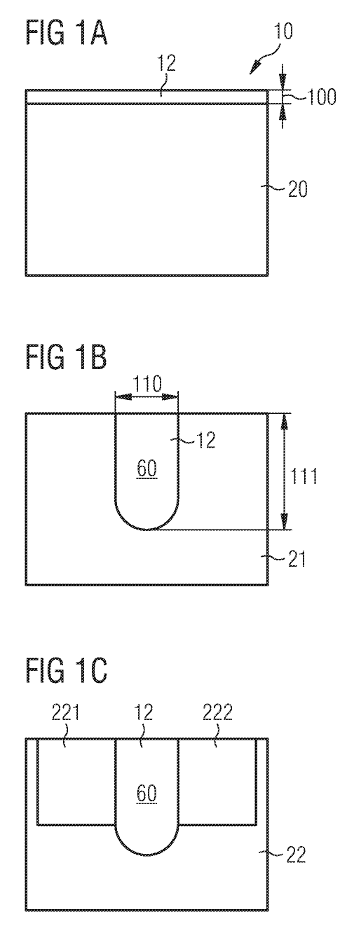

FIG. 1A illustrates a schematic view of a section of an integrated device according to a first embodiment. The illustrated section includes a layer 10 being arranged on a substrate 20. The layer 10 includes an isolating material 12 and has a layer thickness 100. According to this embodiment of the present invention, the substrate 20 may include a semiconductor substrate, such as a silicon substrate, and may further include functional entities, such as transistors, resistors, capacitors, isolators, dielectrics, diodes, light-emitting-diodes, semiconductor lasers, light sensors, conductors, and/or other functional entities as they are known from the manufacturing of highly integrated devices.

The layer 10 includes the isolating material 12, which may include an isolating material such as silicon oxide, silicon nitride, a spin-on-glass (SOG), a spin-on-dielectric (SOD), and/or another insolating material as they are known from the manufacturing of highly integrated devices or a combination thereof. The thickness 100 of the layer 10 may be below 20 nanometers, below 10 nanometers, or below 1 nanometer. A layer 10 with such a thickness 100 may allow for a high integration of functional entities being arranged in the integrated device with an increased packing density, whilst still being reliably isolated from each other.

According to this embodiment, the layer 10 may further include converted material of the substrate 20. Such material of the substrate 20, for example silicon, may form an isolating material, such as silicon oxide, when oxidized. In this way, the isolating material 12 of the layer 10 may be provided in part by converting material of the substrate 20 and in part by deposited material. Such deposited material may further be provided by a provision of silicon, oxygen, siloxane, and/or respective precursors in order to form a silicon oxide layer on the substrate 20.

FIG. 1B illustrates a schematic view of a section of an integrated device according to a second embodiment. A substrate 21 includes a trench 60, the trench 60 having a trench width 110 and a trench depth 111. The trench width 110 may be measured parallel to a substrate plane of the substrate 21, whereas the trench depth 111 may be measured perpendicular to the substrate plane of the substrate 21. According to this embodiment, the trench 60 is filled with the isolating material 12. The trench width 110 may be below 75 nanometers, below 50 nanometers, or below 30 nanometers. The trench depth 111 may be above 450 nanometers, 300 nanometers, or above 180 nanometers. An aspect ratio, being defined as the ratio of the trench depth 111 divided by the trench width 110, may be above 5, above 6, or above 7. The trench 60 may be furthermore filled uniformly and completely by the material 12, such that any voids are absent.

In the case of highly integrated devices, it may be required that trenches with a high aspect ratio are provided, hence, with a minimized trench width 110 in order to save space for the integration of functional entities, and, at the same time, with a sufficient trench depth 111 in order to reliably isolate neighbouring entities within the substrate 20. Increasing the aspect ratio may render it difficult to fill such a trench with a filling material, such as an isolating material. Such a filling may furthermore be required to be complete, comprehensive, and without voids or obstructed trench collars. In the latter case of the formation of obstructing trench collars, material may accumulate at an upper region of the trench or at a trench collar during filling, the accumulated material, once obstructing the trench aperture, inhibiting the further and complete filling of the trench. In the case of voids, unsatisfactory isolation may result due to the uncontrollable nature of voids and their formation. Furthermore, voids may impose problems as far as the dielectric, electric, isolating, and/or optic properties of an isolation trench are concerned.

FIG. 1C illustrates a schematic view of a section of an integrated device according to third embodiment. Accordingly, a substrate 22 includes the trench 60, which is filled with the isolating material 12. Examples and ranges for the respective dimensions of the trench 60 and suitable materials have been given in conjunction with FIGS. 1A and 1B. The trench 60 may be furthermore filled uniformly and completely by the material 12, and may separate and/or isolate a first functional entity 221 from a second functional entity 222. The first functional entity 221 and the second functional entity 222, or parts thereof, may be arranged in and/or on the substrate 22.

According to this embodiment, the trench 60 being filled with the material 12 is arranged in between the first functional entity 221 and the second functional entity 222. Furthermore, the trench 60 depth is such that the trench 60 reliably isolates the two functional entities 221, 222 from each other. For this, the trench depth may exceed or be at least equal to the depth of the functional entities 221, 222. The aspect ratio of the trench 60 is such that the two functional entities 221, 222 may be arranged with a very high packing density while still being reliably isolated from each other. Examples for the functional entities include the aforementioned examples. In the case of the integrated device being a memory device, the functional entities 221, 222 may include memory cells, selection transistors, memory elements, and/or storage capacitors.

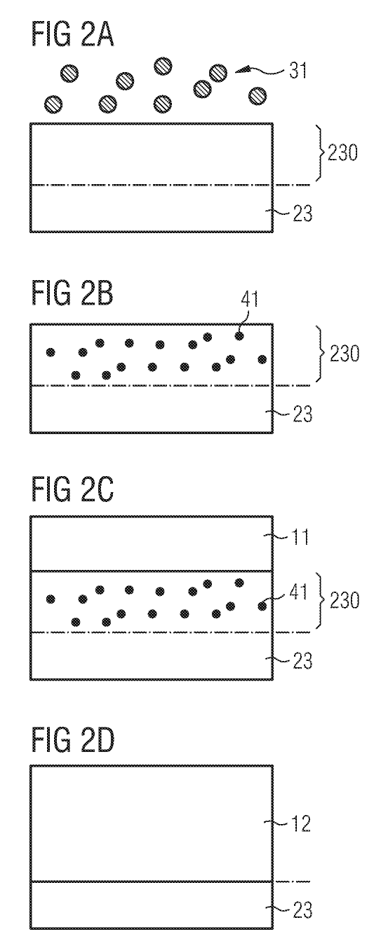

FIGS. 2A through 2D illustrate schematic views of a section of an integrated device in various stages during manufacturing, according to a fourth embodiment of the present invention. Accordingly, a substrate 23, such as the substrate 20, 21, or 22, includes a surface region 230. The surface region 230 is characterized in that it is, in the illustrated stage of manufacturing, accessible from a surrounding environment. In this environment a first process atmosphere may be established, which may include a first precursor 31.

The depth, the surface region 230 reaches into the substrate, measured from the substrate surface being adjacent to the surface region 230, may be furthermore determined by an effective penetration depth of components, such as a first component 41, penetrating into the substrate 24 from the surrounding environment. Therefore, an introduction of a component, such as the first component 41, may be self-limiting, i.e. at a certain depth or thickness the introduction of the component and/or a growth of a composite layer, including the first component and the substrate material, stops.

A process atmosphere, such as the first process atmosphere, may be established, provided, and/or controlled by using pumping, purging, venting, and/or injecting a process gas into a process chamber. Such a process chamber may allow the establishment of a well-controlled and well-defined process atmosphere. In addition to this, a plasma may be employed in the process chamber to initiate, enhance, and/or support a process, for example, it may activate the precursor 31. Furthermore, the substrate 23 and/or the surrounding process atmosphere may be heated to a first temperature. The heating may be effected prior to, during or after the providing of the first process atmosphere. The first temperature may be in a range of 650° C. to 850° C. or in a range of 700° C. to 800° C. The depth of the surface region 230 may be a function of the first process temperature.

According to one embodiment, the first precursor 31 includes any from the group of ammonia and nitrogen. The process atmosphere may further include additional gases, such as an inert gas, in order to allow a tuning of the process, a purging, and/or a removal of process products from the first process atmosphere. The concentration of the first precursor 31 may be in a range of 5 to 100 percent or between 50 and 100 percent, this percentage being given in respect to a carrier gas, such as an inert gas. A pressure of the first process atmosphere may be equal to atmospheric pressure, approximately at 1 bar, or in a range between 50 and 500 torrs. Under such conditions, which may be part of a rapid thermal nitridation (RTN), a first component 41 may be separated from the first precursor 31 and may be incorporated, injected, implanted, or absorbed in or by the surface region 230 of the substrate 23. A process duration may be in a range of 10 seconds to 90 seconds, or 30 seconds. During such an RTN, silicon nitride and/or nitrided silicon may be provided in the surface region 230, wherein an enhanced controllability of the nitride depth, enhanced uniformity, and repeatability may be attained.

As illustrated in FIG. 2B, the substrate 23 includes a first component 41 in the surface region 230. The first component 41 may have been introduced into the surface region 230 of the substrate 23 by using a process as described in conjunction with an embodiment of the present invention. The first component 41 may be comprised by the first precursor 31, may be the same as the first precursor 31, and may be or include nitrogen. A thickness of the surface region 230 may be in a range between 0.5 nanometers and 3.5 nanometers, or in a range between 0.5 nanometers and 1 nanometer.

As illustrated in FIG. 2C, a precursor material 11 is provided on the surface region 230 of the substrate 23. The precursor material 11 may be provided adjacent to the surface region 230, and may cover other parts of the substrate 23 as well. The first material 11 may include silicon, oxygen, nitrogen, siloxane, a spin-on-glass, a spin-on-dielectric, and/or a polisilazane (PSZ). The material 11 may be provided by using spin-coating, a chemical or physical vapor phase deposition, a thermal deposition, a physical deposition, and/or a layer epitaxy, as those techniques are known from the manufacturing of highly integrated devices.

The precursor material 11 and/or other parts of the substrate 23 may be exposed to a process such to cure, anneal, and/or convert the precursor material 11. Such a process may include an SOG-annealing or curing, during which the preliminary material 11 is converted into the isolating material 12. Such a process may include a first stage, during which the precursor material 11 is converted to the isolating material 12. This may include a conversion of polisilazane (PSZ) into silicon oxide. Such a process may include the provision of a second process atmosphere adjacent to the preliminary material 11. Furthermore, this may include a heating of the preliminary material 11 and/or the substrate 23 to a second temperature. This second temperature may be in a range of 550° C. to 1000° C., or in a range of 600° C. to 950° C.

In addition, such a process may include a provision of a third process atmosphere, the third process atmosphere including water vapor, vapour, water, hydrogen, oxygen and/or ozone. Before or after the provision of the process atmosphere, the isolating material 12 and/or the substrate 23 may be heated to a third temperature, the third process temperature being in a range of 700 degrees ° C. to 950° C., or in a range of 750° C. to 900° C. The pressure of the third process atmosphere may be in a range of 50 to 500 torrs, or in a range of 90 to 400 torrs. Such a process may furthermore include a provision of a fourth process atmosphere, the fourth process atmosphere including any from the group of an inert gas, argon, and/or nitrogen. Before and/or after the provision of the fourth process atmosphere, the isolation material 12 and/or the substrate 23 may be heated to a fourth temperature. This fourth temperature may be in a range of 550° C. to 1000° C., or in a range of 600° C. to 950° C. The provision of the fourth process atmosphere and/or the heating to the fourth temperature may be effected in order to densify or increase the density of the isolating material 12.

According to this embodiment, the first component 41 may be released from the surface region 230 of the substrate 23. This release may be effected during any from one of the previously described process stages. Furthermore, a second component may be introduced into the surface region 230 of the substrate 23, in order to convert the substrate material of the surface region 230 into a second isolating material and/or into the isolating material 12, the latter case of the formation of only isolating material 12 illustrated in FIG. 2D. An example of a second component may include oxygen and/or ozone, which may form an oxide of the respective semiconductor material of the substrate 23. For example, the first material 11 may be transformed into silicon oxide, and oxygen may be introduced into the surface region 230 of a silicon substrate, forming silicon oxide. While the first component 41, such as nitrogen, is released, outgased, and/or desorbed during this process, a uniformed silicone oxide layer 12 may be formed in the area of the first material 11 and the surface region 230 of the substrate 23.

The provision of the first component 41 in a respective surface area 230 of the substrate 23 may allow for a well-controlled, and/or limited formation of an isolating material, such as the isolating material 12, and may hence allow for a limiting and/or controlling of the amount of substrate material of the substrate 23 which in converted or altered during a process stage. A thickness of the isolating material 12 or a layer including the isolating material 12 may, in this way, be attained below 5 nanometers, below 3.5 nanometers, or below 1 nanometer. This may further allow to form thin entities with a reduced and minimized feature size of the second material 12, such as a layer or a trench filling thereof. Since the thickness of the isolating material 12 is decreased and/or the material 12 is uniform and homogenous, reliable and miniature isolating entities may be formed for the use in highly integrated electronic and/or optic devices.

The provision of the first component 41 in a respective surface area 230 may further provide a retarding effect on the thermal oxidation of silicon, such that during a curing of a spin-on-glass or spin-on-dielectric the amount of silicon which is oxidised, is controlled and/or limited. Also, the amount of substrate material of the surface region 230 may be tuneable upwards from 0 by adjusting the initial nitridation thickness, i.e. the depth or thickness of the surface region, or the conditions of the curing or oxidation process. The surface region 230, including the substrate material of the substrate 23 and the first component 41, for example silicon and nitrogen, may be seen as a sacrificial layer since it may be converted into an isolating material, such as the isolating material 12, which may be or include silicon oxide.

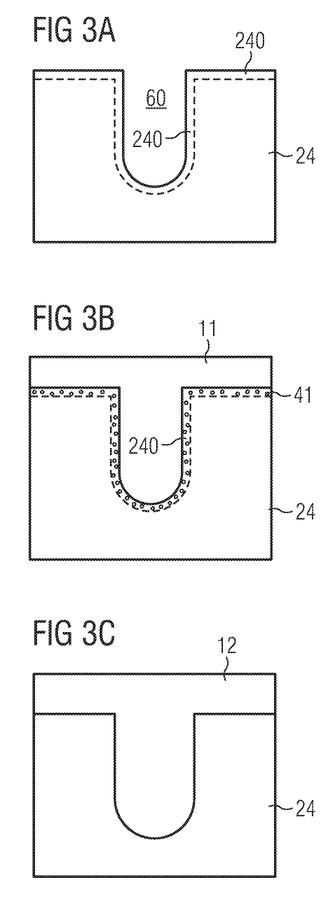

FIGS. 3A through 3C illustrate schematic views of a section of an integrated device in various stages during manufacturing, according to a fifth embodiment of the present invention. Accordingly, a substrate 24 includes a trench 60 which is to be filled with a material. A surface region 240 of the substrate 24 follows a topography of a surface of the substrate 24. The depth of the surface region 240 may be uniform over the entire topography and/or may include a varying effective depth along the surface, due to a local orientation of surface section and/or the presence of a local surface feature, such as a step, a kink, or an edge. A substrate section may be aligned, for example, in parallel with or perpendicular to a substrate plane, such a substrate being in parallel with the substrate's main extension.

For example, a side wall of the trench 60 may be perpendicular to the substrate plane, whereas a top surface of the substrate 24 and a bottom surface of the trench 60 may be parallel to the substrate plane. Along such a varying surface topology, a top surface, a side wall of a trench, and a bottom surface of a trench, the effective depth of the surface region 240 may vary accordingly. For example, the depth of the surface region 240 may be greater along the top surface of the substrate 24 than along the side wall of the trench 60. The substrate 24 may include a substrate 21, 22, or 23, as they have been described in conjunction with one embodiment.

As illustrated in FIG. 3B, the first component 41 may have been incorporated into the surface region 240 and the precursor material 11 may have been provided on the substrate 24, as it has been described in conjunction with FIGS. 2A through 2C. The precursor material 11 may have been provided adjacent to the surface region 240 of the substrate 24. In this stage, the precursor material 11 may already fill the trench 60 uniformly and comprehensively or may include voids.

FIG. 3C illustrates the section after the precursor material 11 has been cured, annealed or converted, such to form the isolating material 12. This curing, effected as being described in conjunction with FIGS. 2A through 2D, results in a complete filling of the trench 60 and may also result in an elimination of voids which may have been present prior to the curing. Furthermore, the substrate material of the surface region 240 of the substrate 24 may have been converted into an isolating material or into the isolating material 12, as illustrated in FIG. 3C.

The provision of the first component 41 in a respective surface area 240 of the substrate 24 may allow for a well-controlled, and/or limited formation of an isolating material, such as the isolating material 12, and may hence allow for a limiting of the amount of substrate material of the substrate 24 which in converted or altered during the curing of the precursor material 11. In this way, the trench 60 may be filled uniformly and comprehensively with an isolating filling material and a trench width, such as the width 110 being defined in conjunction with FIG. 1B, may be attained below 75 nanometers, below 50 nanometers, or below 50 nanometer. At the same time, a trench depth, such as the depth 110 being defined in conjunction with FIG. 1B, may be attained above 450 nanometers, above 300 nanometers, or above 180 nanometers, respectively. The aspect ratio, being defined as the ratio of the trench depth divided by the trench width, may be above 5, above 6, or above 7. The trench 60 may be in this way provide optimized means for isolation in an highly integrated device.

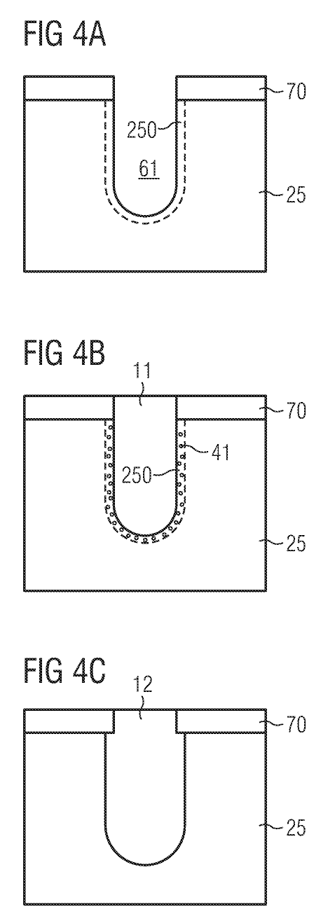

FIGS. 4A through 4C illustrate a section of an integrated device in various stages during manufacturing according to sixth embodiment. As illustrated in FIG. 4A, a top layer 70 is arranged on a substrate 25. A trench 61 is formed in the top layer 70 and in the substrate 25. The substrate 25 may include a substrate 21, 22, 23, or 24, as they have been described in conjunction with one embodiment.

The top layer 70 may include a mask layer, a resist layer, a passivating layer, an/or other entities, such as conductive signal lines, which may cover, at least in part, a top surface of the substrate 25 in this state during manufacturing. Such a cover may provide a shielding of parts of the substrate 25 from a surrounding environment or from the first process atmosphere. The latter may be effected in order to incorporate the first component 41 into the surface region 250, and, hence, the top layer 70 may determine the extension of the surface region 250 in respect to the surface region 240 as this region has been described in conjunction with FIG. 3A.

According to this embodiment, only a limited and restricted surface area of the substrate 25 is accessible through the environment, and the surface region 250 may only be formed in an area of the trench 61. The surface region 250 may be defined such as being that region of the substrate, in which components, such as the first component 41, may be introduced by using their respective provision as a respective precursor in a process atmosphere of a surrounding environment.

As illustrated in FIG. 4B, the first component 41 may have been incorporated into the surface region 250 and the precursor material 11 may have been provided in the trench 61, as it has been described in conjunction with FIGS. 2A through 2C. The precursor material 11 may have been provided adjacent to the surface region 250 of the substrate 25, in the trench 61, and/or on the top layer 70. In this stage, the precursor material 11 may already fill the trench 61 uniformly and comprehensively or may include voids.

FIG. 4C illustrates the section after the precursor material 11 has been cured, annealed or converted, such to form the isolating material 12. This curing, effected as being described in conjunction with FIGS. 2A through 2D, results in a complete filling of the trench 61 and may also result in an elimination of voids which may have been present prior to the curing. Furthermore, the substrate material of the surface region 240 of the substrate 24 may have been converted into an isolating material or into the isolating material 12, as illustrated in FIG. 4C.

The provision of the first component 41 in a respective surface area 250 of the substrate 25 may allow for a well-controlled, and/or limited formation of an isolating material, such as the isolating material 12, and may hence allow for a limiting of the amount of substrate material of the substrate 25 which in converted or altered during the curing of the precursor material 11.

In this way, the trench 61 may be filled uniformly and comprehensively with an isolating filling material and a respective trench width, may be attained below 75 nanometers, below 50 nanometers, or below 50 nanometer. At the same time, a respective trench depth, may be attained above 450 nanometers, above 300 nanometers, or above 180 nanometers, respectively. The aspect ratio, being defined as the ratio of the trench depth divided by the trench width, may be above 5, above 6, or above 7. The trench 61 may be in this way provide optimized means for isolation in an highly integrated device. Furthermore, the trench 61 may provide optimized means for isolation of neighbouring functional entities, which may be comprised by the substrate 25 and/or the top layer 70.

As an example, neighbouring conductive signal lines, comprised by the top layer 70, may be reliably isolated from each other by using the trench 61 being filled with the isolation material 12. Although reliable and sufficient isolation may be provided by a trench 61, integration may still be enhanced, due to the minimized dimensions of the trench 61 and/or the comprehensive filling of the trench 61 with an isolating material, such as the isolating material 12.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of fabricating an integrated device comprising:
providing a substrate, the substrate comprising an exposed surface region;
introducing a first component into the exposed surface region of the substrate;
providing a material on the exposed surface region; and
curing the material on the exposed surface region and releasing the first component from the exposed surface region of the substrate.

2. The method of claim 1, the introduction of the first component comprising:
providing a first process atmosphere adjacent to the surface region, the first process atmosphere comprising the first component; and
heating the substrate to a first process temperature.

3. The method of claim 1, the curing of the material comprising:
providing a second process atmosphere adjacent to the material; and
heating the material to a second process temperature.

4. The method of claim 3, the method further comprising:
providing a third process atmosphere adjacent to the material;
heating the material to a third process temperature.
providing a fourth process atmosphere adjacent to the material; and
heating the material to a fourth process temperature.

5. The method of claim 1, the curing of the material comprising:
a converting of substrate material of the surface region into an isolating material.

6. The method of claim 1, the substrate comprising:
a silicon substrate.

7. The method of claim 1, the introduction of the first component into the exposed surface region of the substrate comprising a nitridation of the exposed surface region of the substrate.

8. A method of fabricating an integrated device comprising:
providing a silicon substrate, the silicon substrate comprising an exposed surface region, the method comprising:
a nitridation of the exposed surface region of the silicon substrate;
providing a precursor material on the exposed surface region; and
curing the precursor material on the surface region, wherein the precursor material is converted into a first isolating material and the nitrogen is released from the surface region of the substrate.

9. The method of claim 8, the curing of the precursor material comprising:
converting the nitrided silicon of the surface region into a second isolating material.

10. The method of claim 9, the first isolating Material and the second isolating material comprising silicon oxide.

11. The method of claim 8, the nitridation of the surface region comprising:
providing a first process atmosphere adjacent to the surface region, the first process atmosphere comprising any from the group of nitrogen and ammonia; and
heating the substrate to a first temperature for a first duration, the first temperature being in a range of 700° C. to 800° C. and the duration being in a range of 5 s to 100 s.

12. The method of claim 8, the precursor material comprising any from the group of silicon, oxygen, nitrogen, siloxane, a spin-on-dielectric, and a spin-on-glass.

13. The method of claim 8, the curing of the precursor material comprising:
a first curing at a first temperature, wherein the precursor material is converted into a first isolating material;
providing a second process atmosphere adjacent to the first isolating material, the second process atmosphere comprising any from the group of water, oxygen, and ozone;
heating the first isolating material to a second temperature, the second temperature being in a range of 700° C. to 950° C.;
providing a third process atmosphere adjacent to the first isolating material, the third process atmosphere comprising any from the group of nitrogen, argon, and an inert gas; and
heating the first isolating material to a third temperature.

14. A method of making an integrated circuit, including filling a trench of a silicon substrate, the method comprising:
nitridation of a surface region of the silicon substrate, the surface region being exposed on a side wall and a bottom wall of the trench;
providing a precursor material on the exposed surface region, the first material comprising any from the group of silicon, oxygen, nitrogen, siloxane, a spin-on-dielectric, and a spin-on-glass; and
curing the precursor material, wherein the precursor material is converted into silicon oxide and the nitrogen is released from the exposed surface region of the silicon substrate.

15. The method of claim 14, the curing of the precursor material comprising:
converting the nitrided silicon of the surface region into silicon oxide.

16. The method of claim 14, the nitridation of the surface region comprising:
providing a first process atmosphere adjacent to the surface region, the first process atmosphere comprising any from the group of nitrogen and ammonia; and
heating the substrate to a first temperature for a first duration, the first temperature being in a range of 700 to 800° C. and the duration being in a range of 5 to 100 s.

17. The method of claim 14, the precursor material comprising any from the group of silicon, oxygen, nitrogen, siloxane, a spin-on-dielectric, and a spin-on-glass.

18. The method of claim 14, the curing of the precursor material comprising:
a first curing at a first temperature, wherein the precursor material is converted into silicon oxide;
providing a second process atmosphere adjacent to the silicon oxide, the second process atmosphere comprising any from the group of water, oxygen, and ozone;
heating the silicon oxide to a second temperature, the second temperature being in a range of 700° C. to 950° C.;
providing a third process atmosphere adjacent to the silicon oxide, the third process atmosphere comprising any from the group of nitrogen, argon, and an inert gas; and
heating the silicon oxide to a third temperature.

19. An integrated device, the integrated device comprising:
a semiconductor substrate, the semiconductor substrate comprising:
a trench, the trench being filled with a filling material; and
a region of the semiconductor substrate adjacent to a side wall and to bottom wall of the trench being converted into the filling material.

20. The integrated device of claim 19, the trench having a trench width parallel to a substrate plane and a trench depth perpendicular to the substrate plane, the trench width being equal to or less than 50 nm, and the trench depth being equal to or greater than 300 nm.

21. The integrated device of claim 19, the converted region of the semiconductor substrate having a thickness in a range of 0.5 nm to 1 nm, the thickness being measured from the side wall of the trench.

22. The integrated device of claim 19, the semiconductor being silicon.

23. The integrated device of claim 22, the filling material comprising silicon oxide.
